(19) United States
(12) Patent Application Publication
(10) Pub. No.: US 2013/0319502 A1
(43) Pub. Date: Dec. 5, 2013

(54) Bifacial Stack Structures for Thin-Film Photovoltaic Cells

(71) Applicants: Vardaan Chawla, Mountain View, CA (US); Yuanda Randy Cheng, Phoenix, AZ (US); Rajeev Narendran Krishnan, Corvallis, OR (US); Ketan Kishor Shah, San Jose, CA (US)

(72) Inventors: Vardaan Chawla, Mountain View, CA (US); Yuanda Randy Cheng, Phoenix, AZ (US); Rajeev Narendran Krishnan, Corvallis, OR (US); Ketan Kishor Shah, San Jose, CA (US)

(73) Assignee: AQT Solar, Inc., Sunnyvale, CA (US)

(21) Appl. No.: 13/485,719

(22) Filed: May 31, 2012

(51) Int. Cl. H01L 31/0224; H01L 31/052

(52) U.S. Cl. 136/246; 136/256

(57) ABSTRACT

In one embodiment, a photovoltaic cell comprises a transparent substrate having an exposed bottom surface for receiving light; a transparent-conducting-oxide layer positioned over the transparent substrate; a chalcogenide photovoltaic-absorber layer positioned over transparent-conducting oxide layer; and another transparent-conducting-oxide layer positioned over the photovoltaic-absorber layer, where the photovoltaic cell is operable to transmit incident light to both sides of the photovoltaic-absorber layer and to absorb incident light at both the top side and the bottom side of the photovoltaic-absorber layer.

### TECHNICAL FIELD

This disclosure generally relates to photovoltaic devices, and more particularly to bifacial thin-film photovoltaic cells.

### BACKGROUND

A typical photovoltaic cell includes a p-n junction, which can be formed by a layer of n-type semiconductor in direct contact with a layer of p-type semiconductor. The electronic differences between these two materials create a built-in electric field and potential difference. When a p-type semiconductor is placed in intimate contact with an n-type semiconductor, then a diffusion of electrons can occur from the region of high electron-concentration (the n-type side of the junction) into the region of low electron-concentration (the p-type side of the junction). The diffusion of carriers does not happen indefinitely, however, because of an opposing electric field created by the charge imbalance. The electric field established across the p-n junction induces separation of charge carriers that are created as result of photon absorption. When light is incident on this junction, the photons can be absorbed to excite pairs of electrons and holes, which are “split” by the built-in electric field, creating a current and voltage.

The majority of photovoltaic cells today are made using relatively thick pieces of high-quality silicon (approximately 200 μm) that are doped with p-type and n-type dopants. The large quantities of silicon required, coupled with the high purity requirements, have led to high prices for solar panels. Thin-film photovoltaic cells have been developed as a direct response to the high costs of silicon technology. Thin-film photovoltaic cells typically use a few layers of thin-films (≦5 μm) of low-quality polycrystalline materials to mimic the effect seen in a silicon cell. A basic thin-film device consists of a substrate (e.g., glass, metal foil, plastic), a metal-back contact, a 1-5 μm semiconductor layer to absorb the light, another semiconductor layer to create a p-n junction and a transparent top conducting electrode to carry current. Since very small quantities of low-quality material are used, costs of thin-film photovoltaic cells can be lower than those for silicon.

Thin-film photovoltaic cells are often manufactured using chalcogenide materials (sulfides, selenides, and tellurides). A chalcogenide is a chemical compound consisting of at least one chalcogen ion (group 16 (VIA) elements in the periodic table, e.g., sulfur (S), selenium (Se), and tellurium (Te)) and at least one more electropositive element. Chalcogenide (both single and mixed) semiconductors have optical band gaps well within the terrestrial solar spectrum, and hence, may be used as photon absorbers in thin-film photovoltaic cells to generate electron-hole pairs and convert light energy to usable electrical energy. The two primary chalcogenide technologies in the thin-film solar space are copper-indium/gallium-sulfide/selenide (CIGS) and cadmium-tellurium (CdTe). CIGS and CdTe photovoltaic cells have lower costs-per-watt produced than silicon-based cells and are making significant inroads into the photovoltaic market. However, CIGS and CdTe technologies are likely to be limited by the potential higher costs, lower material availability, and toxicity of some of their constituent elements (e.g., indium, gallium, tellurium, cadmium). More recently, chalcogenide thin-films using copper-zinc-tin-sulfide/selenide (CZTS) have been developed.

### BRIEF DESCRIPTION OF THE DRAWINGS

The present disclosure is illustrated for example, and not by way of limitation, in the figures of the accompanying drawings and in which like reference numerals refer to similar elements and in which:

FIG. 1 illustrates an example stack structure for a single-stack bifacial photovoltaic cell.

FIG. 2 illustrates an example stack structure for a double-stack bifacial photovoltaic cell.

FIG. 3 illustrates an example solar-cell module system using bifacial photovoltaic cells.

### DESCRIPTION OF EXAMPLE EMBODIMENTS

In the typical photovoltaic-cell design, light can only penetrate through the top transparent-conducting-oxide layer (composed of materials such as ZNO, AZO, or ITO) to be absorbed by the photovoltaic-absorber layer, with no light from the bottom of the photovoltaic cell reaching the photovoltaic-absorber layer. Even in designs where a transparent glass substrate is used, the typical conductive back contact layer such as molybdenum (Mo) is opaque and does not allow light to reach the photovoltaic-absorber layer from the bottom of the photovoltaic-cell. As such, only light that is directly incident to the front of the photovoltaic cell is absorbed in these designs, and any scattered and/or reflected light (for example, light reflected from a surface that the photovoltaic-cell is mounted on) that reaches the back of the photovoltaic cell cannot reach the photovoltaic-absorber layer.

Single-Stack Bifacial Photovoltaic Cells

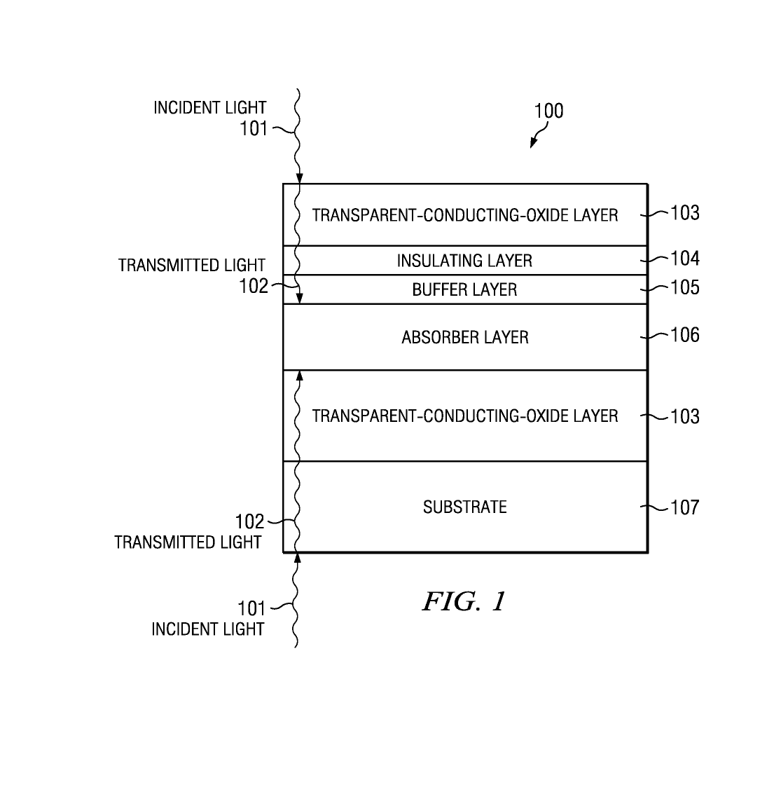

FIG. 1 illustrates an example stack structure for a single-stack bifacial photovoltaic cell 100. In particular embodiments, photovoltaic cell 100 is a thin-film photovoltaic cell. For example, photovoltaic cell 100 may be a Copper-Indium-disulfide (“CIS2”) based cell, a Copper-Indium-diselenide (“CIS”) based cell, a Copper-Indium-Gallium-diselenide (CuInₓGa₍₁₋ₓ₎Se₂, “CIGS”) based cell, a Copper-Zinc-Tin-Sulfur/Selenide (Cu₂ZnSn(S, Se)₄, “CZTS”), or various chalcogenide or chalcopyrite based thin-film photovoltaic cells, among other suitable types of photovoltaic cells. In the example illustrated in FIG. 1, photovoltaic cell 100 comprises a plurality of layers grown or otherwise deposited over a substrate 107. The film stack for photovoltaic cell 100 may comprise one or more of a substrate 107, a bottom transparent-conducting-oxide layer 103, an absorber layer 106, a buffer layer 105, an insulating later 104, a top transparent-conducting-oxide layer 103, or any combination thereof. Although FIG. 1 illustrates a particular arrangement of transparent-conducting-oxide layer 103, insulating layer 104, buffer layer 105, absorber layer 106, and substrate 107, this disclosure contemplates any suitable arrangement of transparent-conducting-oxide layer 103, insulating layer 104, buffer layer 105, absorber layer 106, and substrate 107. Moreover, although FIG. 1 illustrates a particular number of transparent-conducting-oxide layers 103, insulating layers 104, buffer layers 105, absorber layers 106, and substrates 107, this disclosure contemplates any suitable number of transparent-conducting-oxide layers 103, insulating layers 104, buffer layers 105, absorber layers 106, bottom transparent-conducting-oxide layers 103, and substrates 107. As an example and not by way of limitation, stack structure 100 may include multiple transparent- conducting-oxide layers 103, insulating layers 104, buffer layers 105, absorber layers 106, or substrates 107. Furthermore, for the sake of convenience, this disclosure refers to photovoltaic cell 100, and to its particular layers, as having a top side and a bottom side, however this disclosure contemplates photovoltaic cells 100 having any suitable orientation. For example, the substrate 107 may be positioned on the top of photovoltaic cell 100 with respect to the earth.

In particular embodiments, the substrate 107 may be any suitable transparent substrate capable of withstanding high temperatures and/or pressures. The substrate 107 may provide structural support for the film stack. As an example and not by way of limitation, the substrate 107 may be soda-lime glass, a polymer such as polyethylene terephthalate (“PET”), polyacrylates, polycarbonates, polyesters, polysulfones, polyetherimides, silicon, epoxy resin, or silicon-functionalized epoxy resin, another suitable substrate, or any combination thereof, and may have a thickness in the range of approximately 0.7 to 2.3 millimeters (mm), although other thicknesses may be suitable. The substrate 107 may receive incident light 101 on its bottom exposed side and transmit it through to the absorber layer 106 (via one or more intermediate layers) as transmitted light 102. In particular embodiments, the substrate 107 may be replaced by another suitable transparent protective layer or coating, or may be added during construction of a solar module or panel. Alternatively, the layers of the photovoltaic cell 100 may be deposited on a flat substrate (such as a glass substrate intended for window installations), or directly on one or more surfaces of a non-imaging solar concentrator, such as a trough-like or Winston optical concentrator.

In particular embodiments, the substrate 107 may be coated with an electrical contact, such as a transparent-conducting-oxide layer 103. The transparent-conducting-oxide layer 103 may be any suitable electrode material, such as, for example, titanium oxide (e.g., one or more of TiO, TiO₂, Ti₂O₃, or Ti₃O₅), aluminum oxide (e.g., Al₂O₃), cobalt oxide (e.g., one or more of CoO, Co₂O₃, or Co₃O₄), silicon oxide (e.g., SiO₂), tin oxide (e.g., one or more of SnO or SnO₂), zinc oxide (e.g., ZnO), molybdenum oxide (e.g., one or more of Mo, MoO₂, or MoO₃), tantalum oxide (e.g., one or more of TaO, TaO₂, or Ta₂O₅), tungsten oxide (e.g., one or more of WO₂ or WO₃), indium oxide (e.g., one or more of InO or In₂O₃), magnesium oxide (e.g., MgO), bismuth oxide (e.g., Bi₂O₃), copper oxide (e.g., CuO), vanadium oxide (e.g., one or more of VO, VO₂, V₂O₃, V₂O₅, or V₃O₅), chromium oxide (e.g., one or more of CrO₂, CrO₃, Cr₂O₃, or Cr₃O₄), zirconium oxide (e.g., ZrO₂), or yttrium oxide (e.g., Y₂O₃). Additionally, in particular embodiments, transparent-conducting-oxide layer 103 may be doped with one or more of a variety of suitable elements or compounds. For example, transparent-conducting-oxide layer 103 may comprise ZnO or In₂O₃ doped with one or more of aluminum oxide, titanium oxide, zirconium oxide, vanadium oxide, or tin oxide. In another particular embodiment, transparent-conducting-oxide layer 103 may be a multi-layer structure comprising a first layer comprising one or more of zinc oxide, aluminum oxide, titanium oxide, zirconium oxide, vanadium oxide, or tin oxide, and a second layer comprising ZnO or In₂O₃ doped with one or more of aluminum oxide, titanium oxide, zirconium oxide, vanadium oxide, or tin oxide. The transparent-conducting-oxide layer 103 may have a thickness in the range of approximately 500 to 2000 nanometers (nm), although other thicknesses may be suitable. The transparent-conducting-oxide layer 103 and other layers may be transparent to allow light penetration into the absorber layer 106 (directly or via one or more intermediate layers).

In particular embodiments, the absorber layer 106 may be a chalcogenide thin-film, such as, for example, a CIS layer, a CIS2 layer, a CIGS layer, a CZTS layer, another suitable photoactive conversion layer, or any combination thereof. The absorber layer 106 may be either a p-type or an n-type semiconductor layer. Because the conducting layers on both sides of the p-n junction formed by absorber layer 106 and buffer layer 105 are transparent, the photovoltaic cell 100 may be operable to transmit the incident light 101 to both the top side and the bottom side of the absorber layer 106. Consequently, transmitted light 102 may be absorbed on both the top side and bottom side of the photovoltaic-absorber layer, which may increase electrical energy produced by the photovoltaic cell 100. In particular embodiments, absorber layer 106 may actually include a plurality of stacked layers. In particular embodiments, the photovoltaic cell 100 may include multiple absorber layers 106. The plurality of absorber layers 106 or the plurality of stacked layers may vary between, for example, CIS, CIS2, CIGS, CZTS layers. In particular embodiments, absorber layer 106 may have a total thickness in the range of approximately 0.5 to 3 micrometers (μm), although other thicknesses may be suitable. Although this disclosure describes particular types of absorber layers 106, this disclosure contemplates any suitable type of absorber layers 106.

In particular embodiments, a buffer (window) layer 105 may be grown or otherwise deposited over absorber layer 106. The buffer layer 105 may form a p-n junction with the absorber layer 106. The buffer layer 105 may be either a p-type or an n-type semiconducting layer. In particular embodiments, buffer layer 105 may include one or more of the following semiconductor materials: silicon (Si), germanium (Ge), tin (Sn), beta iron silicide (β-FeSi₂), indium antimony (InSb), indium arsenic (InAs), indium phosphate (InP), gallium phosphate (GaP), aluminum phosphate (AlP), gallium arsenic (GaAs), gallium antimony (GaSb), aluminum antimony (AlSb), silicon carbide (SiC), tellurium (Te), zinc antimony (ZnSb), mercury telluride (HgTe), led sulfide (PbS), led selenide (PbSe), led telluride (PbTe), cadmium sulfide (CdS), cadmium selenide (CdSe), cadmium telluride (CdTe), zinc sulfide (ZnS), zinc selenide (ZnSe), zinc telluride (ZnTe), tin telluride (SnTe), copper sulfide (Cu₁₋ₓS (x varies from 1 to 2)), copper selenide (Cu₁₋ₓSe (x varies from 1 to 2)), copper indium disulfide (CuInS₂), copper gallium disulfide (CuGaS₂), copper indium gallium disulfide, (Cu(In₁₋ₓGaₓ)S₂ (x varies from 0 to 1)), copper indium diselenide (CuInSe₂), copper gallium diselenide (CuGaSe₂), copper indium gallium diselenide (Cu(In₁₋ₓGaₓ)Se₂ (x varies from 0 to 1)), copper silver indium gallium disulfide-(Cu₁₋ₓAgₓ)(In_{1-y}Ga_{y})S₂ (x varies from 0 to 1, y varies from 0 to 1)), copper silver indium gallium diselenide (Cu₁₋ₓAgₓ)(In_{1-y}Ga_{y})Se₂ (x varies from 0 to 1, y varies from 0 to 1)), (Cu₁₋ₓAuₓ)InS₂ (x varies from 0 to 1), (Cu₁₋ₓAuₓ)CuGaS₂ (x varies from 0 to 1), (Cu₁₋ₓAuₓ)(In_{1-y}Ga_{y})S₂ (x varies from 0 to 1, y varies from 0 to 1), (Cu₁₋ₓAuₓ)InSe₂(x varies from 0 to 1), (Cu₁₋ₓAuₓ)GaSe₂ (x varies from 0 to 1), (Cu₁₋ₓAuₓ)(In₁₋ₓGaₓ)Se₂ (x varies from 0 to 1), (Ag₁₋ₓAuₓ)(In₁₋ₓGaₓ)Se₂ (x varies from 0 to 1), (Cu_{1-x-y}AgₓAu_{y})(In_{1-z}Ga_{z})Se₂ (x varies from 0 to 1, y varies from 0 to 1, z varies from 0 to 1), (Cu₁₋ₓAuₓ)₂S (x varies from 0 to 1), (Ag₁₋ₓAuₓ)₂S (x varies from 0 to 1), (Cu_{1-x-y} AgₓAu_{y})₂S (x varies from 0 to 1, y varies from 0 to 1), indium sulfide (In₂S₃), indium selenide (In₂Se₃), aluminum nitride (AlN), indium nitride (InN), gallium nitride (GaN), bismuth sulfide (Bi₂S₃), antimony sulfide (Sb₂S₃), silver sulfide (Ag₂S), tungsten sulfide (WS₂), tungsten selenide (WSe₂), molybdenum sulfide (MoS₂), molybdenum selenide (MoSe₂), tin sulfide (SnSₓ (x varies from 1 to 2)), tin selenide (SnSeₓ (x varies from 1 to 2)), or copper tin sulfide (Cu₄SnS₄). Buffer layer 105 may have a thickness in the range of approximately 30 to 70 nm, although other thicknesses may be suitable.

In particular embodiments, an insulating layer 104 may be grown or otherwise deposited over buffer layer 105. The insulating layer may improve the efficiency of the photovoltaic cell 100 by limiting the detrimental effects of any non-uniformity in the thin-film layer. For example, insulating layer 104 may be formed from ZnO and have a thickness in the range of approximately 70 to 100 nm, although other thicknesses may be suitable. Another transparent-conducting-oxide layer 103 may then be deposited over the insulating layer 104. In particular embodiments. This top transparent-conducting oxide layer 103 may have a thickness in the range of approximately 0.2 to 1.5 μm, although other thicknesses may be suitable. The top transparent-conducting-oxide layer 103 may receive incident light 101 and transmit it down towards the absorber layer 106 as transmitted light 102 (directly or via one or more intermediate layers).

In particular embodiments, the photovoltaic cell 100 may be coated with a transparent protective layer on the top side, the bottom side, or both. The protective layer may protect the photovoltaic cell 100 from weathering and other physical damage without interfering with the collection of incident light 101. As an example and not by way of limitation, the transparent protective layer may comprise ethylene-vinyl acetate (EVA), another suitable transparent protective material, or any combination thereof

Those of skill in the art will appreciate that FIG. 1 is not to scale as the sum total of the thicknesses of layers 103, 104, 105, 106, and 107 may be, in particular embodiments, still on the order of or less than 1% of the thickness of substrate 107, and thus on the order of or less than 1% of the thickness of the entire photovoltaic cell and may, in some embodiments, be less than one-tenth of 1% of the thickness of the entire photovoltaic cell.

Double-Stack Bifacial Photovoltaic Cells

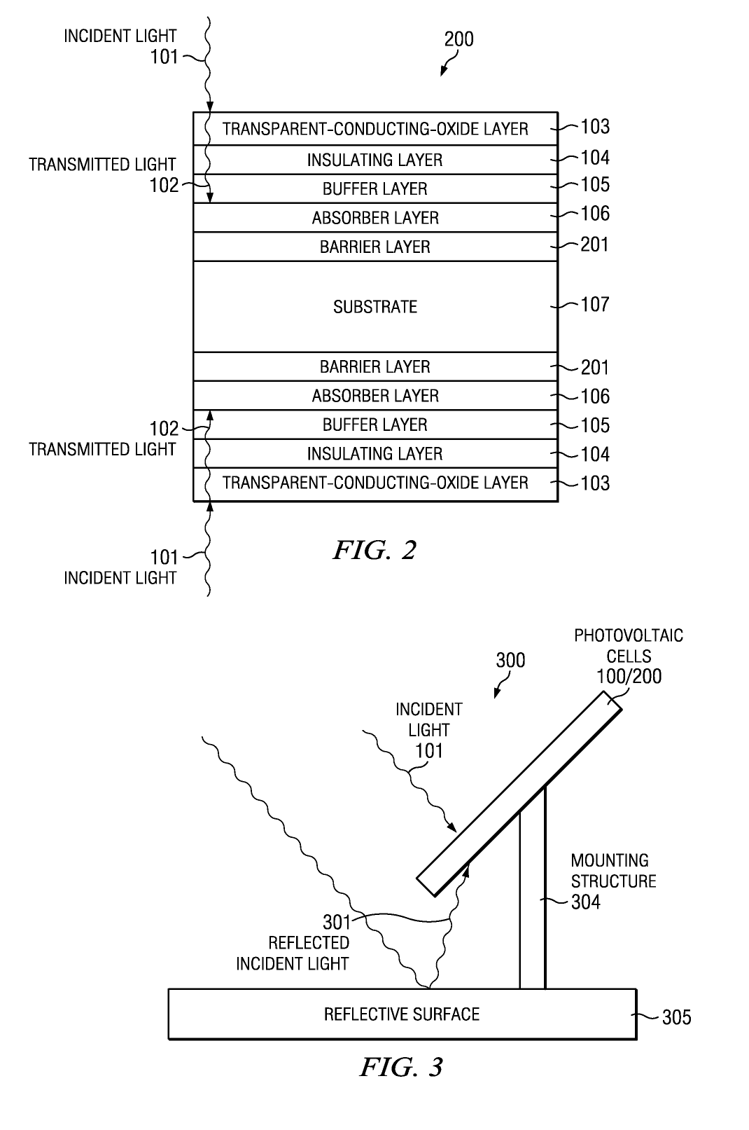

FIG. 2 illustrates an example stack structure for a double-stack bifacial photovoltaic cell 200. In particular embodiments, double-stack cell 200 is a thin-film photovoltaic cell. For example, double-stack cell 200 may be a Copper-Indium-disulfide (“CIS2”) based cell, a Copper-Indium-diselenide (“CIS”) based cell, a Copper-Indium-Gallium-diselenide (CuInₓGa₁₋ₓ)Se₂, “CIGS”) based cell, a Copper-Zinc-Tin-Sulfur/Selenide (Cu₂ZnSn(S, Se)₄, “CZTS”), or various chalcogenide or chalcopyrite based thin-film photovoltaic cells, among other suitable types of photovoltaic cells. In the example illustrated in FIG. 2, double-stack cell 200 comprises a plurality of layers grown or otherwise deposited over a substrate 107. The film stack for double-stack cell 200 may comprise one or more of a substrate 107, a barrier layer 201, an absorber layer 106, a buffer layer 105, an insulating later 104, and a transparent-conducting-oxide layer 103, or any combination thereof. Although FIG. 2 illustrates a particular arrangement of transparent-conducting-oxide layer 103, insulating layer 104, buffer layer 105, absorber layer 106, barrier layer 201, and substrate 107, this disclosure contemplates any suitable arrangement of transparent-conducting-oxide layer 103, insulating layer 104, buffer layer 105, absorber layer 106, barrier layer 201, and substrate 107. Moreover, although FIG. 2 illustrates a particular number of transparent-conducting-oxide layers 103, insulating layers 104, buffer layers 105, absorber layers 106, barrier layers 201, and substrates 107, this disclosure contemplates any suitable number of transparent-conducting-oxide layers 103, insulating layers 104, buffer layers 105, absorber layers 106, barrier layers 201, and substrates 107. As an example and not by way of limitation, photovoltaic cell 200 may include multiple transparent-conducting-oxide layer 103, insulating layer 104, buffer layer 105, absorber layer 106, barrier layer 201, and substrate 107.

In particular embodiments, the substrate 107 may be any suitable substrate capable of withstanding high temperatures and/or pressures, as described previously. Furthermore, in particular embodiments, the substrate 107 in double-stack cell 200 may be an electrically-conducting material, such as, for example, stainless steel, aluminum, tungsten, molybdenum, copper, a semiconducting material, another suitable electrically-conducting material, or any combination thereof. A substrate 107 comprising electrically-conducting material may function as a hole-conducting layer for the double-stack cell 200. In such embodiments, an electrically-conducting substrate 107 may act as a hole-transport layer for both the absorber layer 106 above the substrate 107 as well as the absorber layer 106 below the substrate 107. Alternatively, in particular embodiments, the substrate 107 may be a substantially non-conducting or insulating material, such as, for example, glass, Si, Ge, GaAs, Al₂O₃, graphite, another material unsuitable for conducting electricity, or any combination thereof. If the substrate 107 is not electrically conducting, the substrate 107 may be coated on the top and bottom sides with an electrical contact consisting of any suitable electrode material, such as, for example, Mo, W, Al, Fe, Cu, Sn, Zn, another suitable electrode material, or any combination thereof, having a thickness in the range of approximately 500 to 5000 nanometers (nm), although other thicknesses may be suitable. In particular embodiments, the layers of the double-stack cell 200 may be deposited on a flat substrate (such as a glass substrate intended for window installations), or directly on one or more surfaces of a non-imaging solar concentrator, such as a trough-like or Winston optical concentrator.

In particular embodiments, a barrier layer 201 may be grown or otherwise deposited over both the top side and the bottom side of the substrate 107. The barrier layer 201 may function as a barrier between the substrate 107 and the absorber layer 106 to prevent the substrate 107 or any coatings on the substrate 107 from contaminating the absorber layer 106. The barrier layer 201 may consist of Cr, Mo, Cu, TiN, TiO₂, SiN, SiC, W, another suitable material, or any combination thereof, having a thickness in the range of approximately 5 to 500 nanometers (nm), although other thicknesses may be suitable.

In particular embodiments, an absorber layer 106 is then deposited on each barrier layer 201 on either side of the substrate 107. The absorber layer 106 in double-stack cell 200 may be any suitable photoactive conversion layer, as described previously. Because both sides of the double-stack cell 200 are exposed able to receive incident light 101, the double-stack cell 200 may be operable to transmit the incident light 101 to both the top and bottom absorber layers 106. Consequently, transmitted light 102 may be absorbed on both the top side and bottom side of the double-stack cell 200, which may increase electrical energy produced by the double-stack cell 200.

In particular embodiments, a buffer (window) layer 105 may be grown or otherwise deposited over each absorber layer 106. The buffer layer 105 may form a p-n junction with the absorber layers 106, and may comprise any suitable semiconductor materials, as described previously.

In particular embodiments, an insulating layer 104 may be grown or otherwise deposited between the buffer layers 105 and the transparent-conducting-oxide layers 103, as described previously.

Those of skill in the art will appreciate that FIG. 2 is not to scale as the sum total of the thicknesses of layers 103, 104, 105, 106, 201, and 107 may be, in particular embodiments, still on the order of or less than 1% of the thickness of substrate 107, and thus on the order of or less than 1% of the thickness of the entire photovoltaic cell and may, in some embodiments, be less than one-tenth of 1% of the thickness of the entire photovoltaic cell.

Solar Module System Using Bifacial Photovoltaic Cells

FIG. 3 illustrates an example solar module system 300 using bifacial photovoltaic cells. In particular embodiments, one or more single-stack bifacial photovoltaic cells 100, double-stack bifacial photovoltaic cells 200, or any combination thereof may be incorporated into a solar module system 300. The solar module system 300 may increase the total amount of light absorbed by the photovoltaic cells 100/200 by exposing the front side of the photovoltaic cells 100/200 to incident light 101 and exposing the back side of the photovoltaic cells 100/200 to reflected incident light 301. As an example and not by way of limitation, solar module system 300 may include a module of photovoltaic cells 100/200 mounted a fixed distance from a reflective surface 305 by a mounting structure 304. Reflected incident light 301 may be directed to the back side of the photovoltaic cells 100/200 by the reflective surface, increasing the overall light collected by the system. Experimental data shows that a substantial amount of light is reflected or scattered by the surfaces that photovoltaic cells are typically mounted on, such as asphalt or roofing material. A photovoltaic cell capable of collecting this reflected or scattered light can increase the amount of light it collects, and therefore its power output, by approximately10% to 30%. In particular embodiments, solar module system 300 may be installed with the photovoltaic cells 100/200 in a substantially vertical orientation. While a vertically-oriented installation may not increase the total amount of light collected by each photovoltaic cell 100/200 in the solar module system 300, the vertical installation may decrease the total space taken up by each module of photovoltaic cells 100/200, allowing for the installation of a greater number of solar modules within a particular area.

Although FIG. 3 illustrates a particular arrangement of photovoltaic cells 100/200, reflective surface 305, and mounting structure 304, this disclosure contemplates any suitable arrangement of photovoltaic cells 100/200, reflective surface 305, and mounting structure 304. Moreover, although FIG. 3 illustrates a particular number of photovoltaic cells 100/200, reflective surface 305, and mounting structure 304, this disclosure contemplates any suitable number of photovoltaic cells 100/200, reflective surface 305, and mounting structure 304. As an example and not by way of limitation, solar module system 300 may include multiple photovoltaic cells 100/200, reflective surfaces 305, and mounting structures 304.

In particular embodiments, reflective surface 305 may be comprised of a mirrored surface, lightly-colored or otherwise reflective cement, metal (e.g., stainless steel, aluminum, etc.), any other suitably reflective material, or any combination thereof. In particular embodiments, mounting structure 304 may be a rod, spacer, mount, or other rigid structure attached capable of supporting the weight of the photovoltaic cells 100/200 and maintaining their position at a fixed-distance from reflective surface 305 such that the reflective surface 305 may catch incident light 101 not absorbed by the front side of photovoltaic cells 100/200 and reflect it back toward the back side of photovoltaic cells 100/200 as reflected incident light 301. Although this disclosure describes particular types of mounting structures 304 and reflective surfaces 305, this disclosure contemplates any suitable type of mounting structures 304 and reflective surfaces 305.

Miscellaneous

Herein, “or” is inclusive and not exclusive, unless expressly indicated otherwise or indicated otherwise by context. Therefore, herein, “A or B” means “A, B, or both,” unless expressly indicated otherwise or indicated otherwise by context. Moreover, “and” is both joint and several, unless expressly indicated otherwise or indicated otherwise by context. Therefore, herein, “A and B” means “A and B, jointly or severally,” unless expressly indicated otherwise or indicated otherwise by context. Furthermore, “a”, “an,” or “the” is intended to mean “one or more,” unless expressly indicated otherwise or indicated otherwise by context. Therefore, herein, “an A” or “the A” means “one or more A,” unless expressly indicated otherwise or indicated otherwise by context.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, this disclosure encompasses any suitable combination of one or more features from any example embodiment with one or more features of any other example embodiment herein that a person having ordinary skill in the art would comprehend. Furthermore, reference in the appended claims to an apparatus or system or a component of an apparatus or system being adapted to, arranged to, capable of, configured to, enabled to, operable to, or operative to perform a particular function encompasses that apparatus, system, component, whether or not it or that particular function is activated, turned on, or unlocked, as long as that apparatus, system, or component is so adapted, arranged, capable, configured, enabled, operable, or operative.

What is claimed is:

1. A photovoltaic cell, comprising:
a transparent substrate having an exposed bottom surface operable to receive incident light;
a bottom transparent-conducting-oxide layer positioned over the transparent substrate;
a chalcogenide photovoltaic-absorber layer having a top side and a bottom side, the bottom side being positioned over the bottom transparent-conducting-oxide layer; and
a top transparent-conducting-oxide layer positioned over the top side of the photovoltaic-absorber layer having an exposed top surface operable to receive incident light;
wherein the photovoltaic cell is operable to transmit incident light to both the top side and the bottom side of the photovoltaic-absorber layer, and wherein the photovoltaic-absorber layer is operable to absorb incident light at both the top side and the bottom side of the photovoltaic-absorber layer.

2. The photovoltaic cell of claim 1, wherein the bottom transparent-conducting oxide layer comprises AZO (Al₂O₃ doped ZnO) or ITO (Indium Tin Oxide or tin-doped oxide).

3. The photovoltaic cell of claim 1, wherein the photovoltaic-absorber layer comprises one or more of a Copper-Zinc-Tin-Sulfur/Selenide (CZTS) material layer or a Copper-Indium-Gallium-Diselenide (CIGS) material layer.

4. The photovoltaic cell of claim 1, further comprising a buffer layer positioned between the photovoltaic-absorber layer and the top transparent-conducting-oxide layer.

5. The photovoltaic cell of claim 4, wherein the buffer layer comprises an n-type semiconducting material.

6. The photovoltaic cell of claim 1, further comprising an insulating layer positioned beneath the top transparent-conducting-oxide layer.

7. The photovoltaic cell of claim 7, wherein the insulating layer comprises a Zinc Oxide (ZnO) material layer.

8. The photovoltaic cell of claim 1, wherein the top side, the bottom side, or both sides of the photovoltaic-absorber layer are coated with a transparent protective layer.

9. The photovoltaic cell of claim 8, wherein the transparent protective layer comprises EVA.

10. The photovoltaic cell of claim 1, wherein the top transparent-conducting-oxide layer comprises AZO (Al₂O₃ doped ZnO) or ITO (Indium Tin Oxide or tin-doped oxide).

11. A solar-cell module system, comprising:
a plurality of photovoltaic cells of claim 1 arranged on a plane, having a front side and a back side; and
a reflective surface for directing incident light to the back side of the photovoltaic cells, wherein the plurality of photovoltaic cells are mounted at a fixed distance from the reflective surface by a mounting structure;
wherein the photovoltaic cells receive incident light on the front side from a natural source and receive incident light on the back side from the reflective surface.

12. A photovoltaic cell, comprising:
a substrate;
a top chalcogenide photovoltaic-absorber layer having a top side and a bottom side, the bottom side being positioned over the substrate;
a bottom chalcogenide photovoltaic-absorber layer having a top side and a bottom side, the top side being positioned under the substrate;
a top transparent-conducting-oxide layer positioned over the top insulating layer, the top transparent-conducting-oxide layer having an exposed top surface; and
a bottom transparent-conducting-oxide layer positioned under the bottom insulating layer, the bottom transparent-conducting-oxide layer having an exposed bottom surface;
wherein the photovoltaic cell is operable to transmit incident light to both the top photovoltaic-absorber layer and the bottom photovoltaic-absorber layer, and wherein the top photovoltaic-absorber layer is operable to absorb incident light at the top side of the photovoltaic cell and the bottom photovoltaic-absorber layer is operable to absorb incident light at the bottom side of the photovoltaic cell.

13. The photovoltaic cell of claim 12, further comprising an insulating layer positioned over the top photovoltaic-absorber layer and an insulating layer positioned under the bottom photovoltaic-absorber layer.

14. The photovoltaic cell of claim 12, wherein the substrate is an electrically conducting substrate.

15. The photovoltaic cell of claim 14, wherein the electrically conducting substrate comprises stainless steel.

16. The photovoltaic cell of claim 12, wherein the substrate is an insulating substrate.

17. The photovoltaic cell of claim 16, wherein the substrate is coated with conducting layers on both top and bottom surfaces.

18. The photovoltaic cell of claim 12, wherein a barrier layer is coated on both sides of the substrate.

19. The photovoltaic cell of claim 18, wherein the barrier is comprised of one of Chromium (Cr), Molybdenum (Mo) or Copper (Cu).

20. The photovoltaic cell of claim 12, wherein the top and bottom photovoltaic-absorber layers are comprised of one or more of a Copper-Zinc-Tin-Sulfur/Selenide (CZTS) material layer or a Copper-Indium-Gallium-Diselenide (CIGS) material layer.

21. The photovoltaic cell of claim 12, wherein the top and bottom transparent-conducting-oxide layers are comprised of AZO (Al₂O₃ doped ZnO) or ITO (Indium Tin Oxide or tin-doped oxide).
